(19) United States
(12) Patent Application Publication
(10) Pub. No.: US 2013/0207745 A1
(43) Pub. Date: Aug. 15, 2013

(54) 3D RF L-C FILTERS USING THROUGH GLASS VIAS

(71) Applicants: Changhan Yun, San Diego, CA (US); Chengjie Zuo, San Diego, CA (US); Chi Shun Lo, San Diego, CA (US); Jonghae Kim, San Diego, CA (US); Mario F. Velez, San Diego, CA (US)

(72) Inventors: Changhan Yun, San Diego, CA (US); Chengjie Zuo, San Diego, CA (US); Chi Shun Lo, San Diego, CA (US); Jonghae Kim, San Diego, CA (US); Mario F. Velez, San Diego, CA (US)

(73) Assignee: QUALCOMM Incorporated, San Diego, CA (US)

(21) Appl. No.: 13/419,876

(22) Filed: Mar. 14, 2012

Related U.S. Application Data
(60) Provisional application No. 61/597,953, filed on Feb. 13, 2012.

(51) Int. Cl. H03H 7/01; H05K 3/30

(52) U.S. Cl. 333/185; 29/832; 333/175

(57) ABSTRACT

Three-dimensional (3D) Radio Frequency (RF) inductor-capacitor (LC) band pass filters having through-glass-vias (TGVs). One such L-C filter circuit includes a glass substrate, a first portion of a first inductor formed on a first surface of the glass substrate, a second portion of the first inductor formed on a second surface of the glass substrate, and a first set of TGVs configured to connect the first and second portions of the first inductor. Additionally the L-C filter circuit can include a second inductor similar to the first inductor, and a metal-insulator-metal (MIM) capacitor formed between the first and second inductor, such that the first and second inductor are coupled through the MIM capacitor.

### FIELD OF DISCLOSURE

Disclosed embodiments are related to radio frequency (RF) filters. More particularly, exemplary embodiments are directed to three-dimensional (3D) RF inductor-capacitor (LC) band pass filters comprising through-glass-vias (TGVs).

### BACKGROUND

Inductors are used extensively in analog circuits and signal processing. Inductors in conjunction with capacitors and other components can be used to form tuned circuits or L-C filters that can emphasize or filter out specific signal frequencies. Inductance (measured in henries H) is an effect which results from the magnetic field that forms around a current-carrying conductor. Factors such as the number of turns of the inductor, the area of each loop/turn, and the material it is wrapped around affect the inductance. The quality factor (or Q) of an inductor is a measure of its efficiency. The higher the Q of the inductor, the closer it approaches the behavior of an ideal, lossless, inductor. The Q of the inductor is directly proportional to its inductance L and inversely proportional to its internal electrical resistance R. Accordingly, the Q of the inductor may be increased by increasing L and/or by reducing R.

It is known in the art for designing small inductors for use in integrated circuits by etching them directly on a printed circuit board by laying out a trace in a spiral pattern. However, such planar inductors do not exhibit high Q. Moreover, planar inductors do not lend themselves well for coupling with other inductive elements in tuned circuits, or in other words, they do not exhibit a high coefficient of coupling K.

For analog RF and system on chip (SOC) applications, three dimensional inductors can be constructed as a coil of conducting material, such as copper wire or other suitable metal, wrapped around a core. The core may be air or may include a silicon substrate, glass, or magnetic material. Core materials with a higher permeability than air confine the magnetic field closely to the inductor, thereby increasing the inductance of the inductor. While three dimensional inductors that are known in the art exhibit better coefficient of coupling K than planar inductors, current technology has imposed limitations on the Q factor that is achievable for these inductors. For example, inductors formed on a glass substrate, or wrapped around a core made of glass can exhibit high permeability, coefficient of coupling, and Q factor. However, known techniques to construct inductors on a glass substrate rely on vias such as through-silicon-vias (TSVs) which take away from the desirable characteristics of glass substrates.

Accordingly, there is a need in the art for inductors and concomitant tuned circuit designs that exhibit high Q and high coefficient of coupling K.

### SUMMARY

Exemplary embodiments of the invention are directed to systems and method for radio frequency (RF) filters. More particularly, exemplary embodiments are directed to three-dimensional (3D) RF inductor-capacitor (L-C) band pass filters comprising through-glass-vias (TGVs).

For example, an exemplary embodiment is directed to a method of forming an L-C filter circuit on a glass substrate comprising: forming a first portion of a first inductor on a first surface of the glass substrate; forming a second portion of the first inductor on a second surface of the glass substrate; and connecting the first and second portions of the first inductor via through glass vias (TGVs).

Another exemplary embodiment is directed to an L-C filter circuit comprising: a glass substrate; a first portion of a first inductor formed on a first surface of the glass substrate; a second portion of the first inductor formed on a second surface of the glass substrate; and a first set of through-glass-vias (TGVs) configured to connect the first and second portions of the first inductor.

Another exemplary embodiment is directed to a method of forming an L-C filter circuit on a glass substrate comprising; step for forming a first portion of a first inductor on a first surface of the glass substrate; step for forming a second portion of the first inductor on a second surface of the glass substrate; and step for connecting the first and second portions of the first inductor via through-glass-vias (TGVs).

Yet another exemplary embodiment is directed to an L-C filter circuit comprising: a substrate means formed of glass; a first portion of a first inductance means formed on a first surface of the substrate means; a second portion of the first inductance means formed on a second surface of the substrate means; and a first set of through-glass-vias (TGVs) configured to connect the first and second portions of the first inductance means.

Yet another exemplary embodiment is directed to an L-C filter circuit comprising: a first L-C tank comprising a first inductor and a first capacitor coupled between a high voltage supply and ground; a second L-C tank comprising a second inductor and a second capacitor coupled between the high voltage supply and ground; and an L-C filter means coupling the first L-C tank and the second L-C tank, wherein the first and second inductors are three-dimensional solenoid inductors formed on a first and second surface of a glass substrate using through-glass-vias (TGVs), and wherein the first capacitor is formed as a metal-insulator-metal (MIM) capacitor between the first inductor and the second inductor on the first surface of the glass substrate, and the second capacitor is formed as a MIM capacitor between the second inductor and the L-C filter means on the first surface of the glass substrate.

### BRIEF DESCRIPTION OF THE DRAWINGS

The accompanying drawings are presented to aid in the description of embodiments of the invention and are provided solely for illustration of the embodiments and not limitation thereof.

FIG. 1A illustrates an exemplary inductor formed on a glass substrate using TGVs.

FIG. 1B illustrates an exemplary inductor formed on a glass substrate using TGVs and further including a magnetic core.

FIG. 2 illustrates two exemplary inductors with their magnetic fields aligned.

FIG. 3A illustrates an exemplary L-C BPF designed with inductors and capacitors using TGVs.

FIG. 3B illustrates the corresponding circuit-level schematic representation of the BPF of FIG. 3A

FIG. 3C illustrates the frequency response characteristic of the L-C BPF of FIGS. 3A-B.

FIG. 4A illustrates another exemplary L-C BPF designed with inductors and capacitors using TGVs.

FIG. 4B illustrates the corresponding circuit-level schematic representation of the L-C BPF of FIG. 4A.

FIG. 4C illustrates the frequency response characteristic of the L-C BPF of FIGS. 4A-B.

FIG. 5A illustrates yet another exemplary L-C BPF designed with inductors and capacitors using TGVs.

FIG. 5B illustrates the corresponding circuit-level schematic representation of the L-C BPF of FIG. 5A.

FIG. 5C illustrates the frequency response characteristic of the L-C BPF of FIGS. 5A-B.

FIG. 6A illustrates yet another exemplary L-C BPF designed with inductors and capacitors using TGVs.

FIG. 6B illustrates the frequency response characteristic of the L-C BPF of FIG. 6A.

FIG. 7A illustrates yet another exemplary L-C BPF designed with inductors and capacitors using TGVs.

FIG. 7B illustrates the frequency response characteristic of the L-C BPF of FIG. 7A.

FIG. 8 is a flow-chart representation of a method of forming an inductor on a glass substrate using TGVs according to exemplary embodiments.

FIG. 9 illustrates an exemplary wireless communication system 900 in which an embodiment of the disclosure may be advantageously employed.

### DETAILED DESCRIPTION

Aspects of the invention are disclosed in the following description and related drawings directed to specific embodiments of the invention. Alternate embodiments may he devised without departing from the scope of the invention. Additionally, well-known elements of the invention will not be described in detail or will be omitted so as not to obscure the relevant details of the invention.

The word “exemplary” is used herein to mean “serving as an example, instance, or illustration.” Any embodiment described herein as “exemplary” is not necessarily to be construed as preferred or advantageous over other embodiments. Likewise, the term “embodiments of the invention” does not require that all embodiments of the invention include the discussed feature, advantage or mode of operation.

The terminology used herein is for the purpose of describing particular embodiments only and is not intended to be limiting of embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

Exemplary embodiments are directed to tuned circuits such as L-C band pass filters (BPFs) using inductive and capacitive elements which may be formed on glass substrate. Moreover, embodiments may include through-glass-vias (TGVs) to form connections between a first surface and a second surface of the glass substrates in order to form 3D BPFs. In this manner, embodiments may be configured to confine magnetic fields of the 3D BPFs to the glass substrates, thus enhancing their performance and reducing fluctuations in their corresponding frequency response characteristics. Embodiments using aforementioned TGVs may also be directed to particular circuit topologies for 3D L-C BPFs comprising inductor-coupling between L-C tanks in order to remove undesirable spurious fluctuations in the pass band of the frequency response.

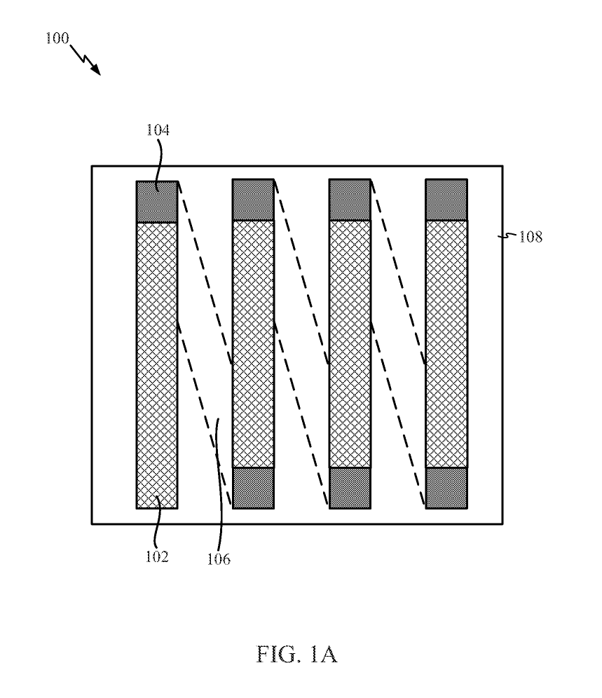

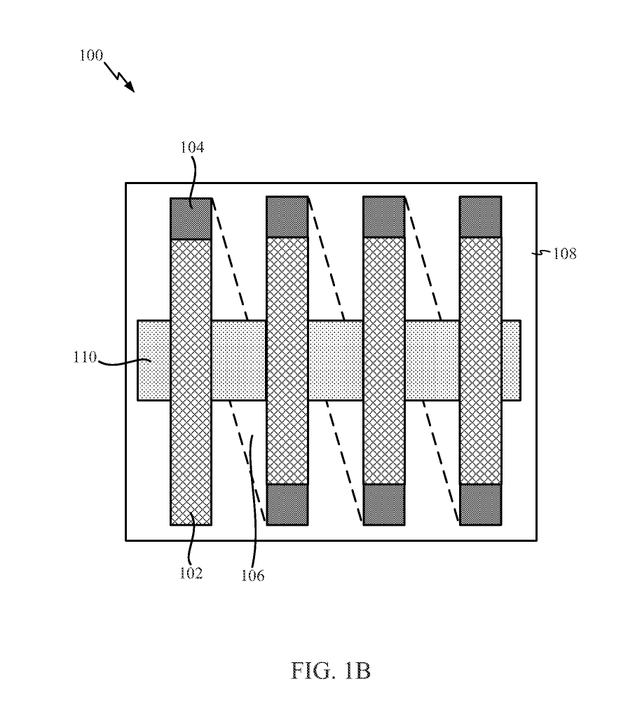

With reference now to FIG. 1A, a 3D solenoid inductor generally designated as 100 and configured according to exemplary embodiments is illustrated. Inductor 100 may be formed on substrate 108 which may be a glass substrate. Glass substrates may facilitate low dielectric loss and substantially eliminate eddy current loss. In inductor 100, a first portion 102 is illustrated in the shaded portions. First portion 102 may be formed of a conductive material such as a metal and disposed on a first surface such as a top surface of substrate 108. Second portion 106 illustrated by ghost lines may be similarly formed of a conductive material and disposed on a second surface such as a bottom surface of substrate 108. First portion 102 and second portion 106 may be connected by TGVs 104 (illustrated by dark shading) which pass through substrate 108. As shown, second portion 106 may be formed at an angle relative to first portion 102 in order to allow for overlapping connection points of TGVs 104.

In comparison to vias formed according to previously known technologies, the use of TGVs in exemplary embodiments to connect first portion 102 and second portion 106 through substrate 108 (which may be formed of glass) will lead to lower losses in inductance L of inductor 100. Further, thicker metal lines may be used for forming first portion 102 and second portion 106 over a glass substrate. Moreover, TGVs may be formed of greater thickness than previously known technologies for vias. Accordingly, thicker metal lines and vias will lead to lower resistance R through the turns of inductor 100. As will be seen, a higher inductance L along with a lower resistance R will contribute to a higher Q factor for inductor 100. Further, skilled persons will recognize that the 3D configuration of inductor 100 on glass substrate 108 will also confine the magnetic fields to the glass substrate, and thus further improve quality and reduce losses.

In some embodiments, a core such as a magnetic core may be provided to further improve the inductance of exemplary inductors. For example, with reference to FIG. 1B, core 110 is illustrated. Core 110 may be made of a magnetic material and provided within substrate 108, thereby increasing permeability of the core. Known magnetic materials such as Co Fe, CoFeB, NiFe, etc. may be used for forming core 110 within substrate 108. It will be understood that including core 110 is optional, and without a magnetic core, the permeability of substrate 108 formed of glass may be similar to that of an air core.

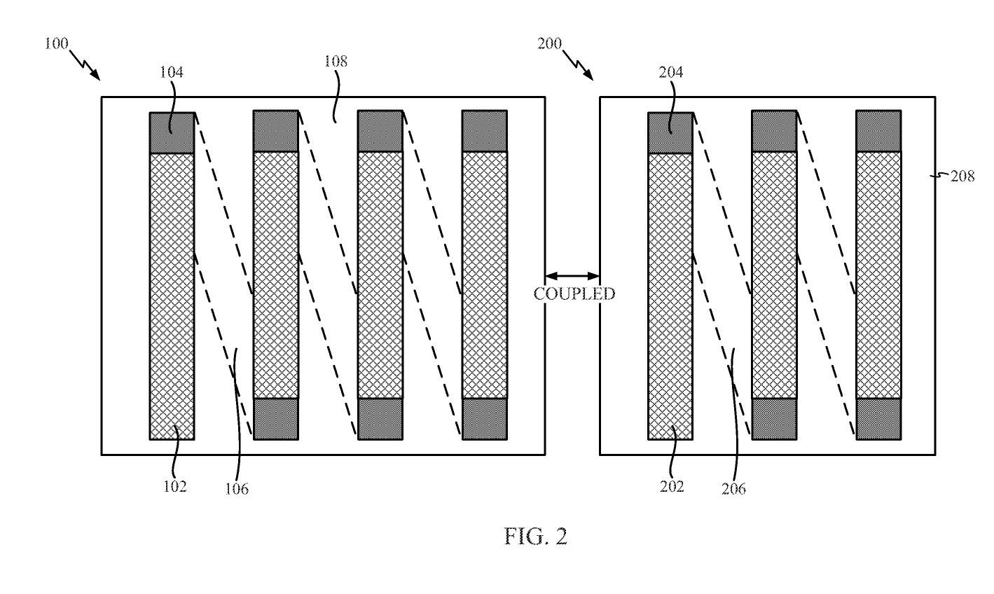

With reference now to FIG. 2, another embodiment is shown, wherein a second 3D solenoid inductor 200 is provided. Inductor 200 is positioned in close proximity to inductor 100 described above, in such a manner as to align their respective magnetic fields. Aligning the magnetic fields in this manner may enable a positive mutual inductance coupling between inductor 100 and 200, thereby enhancing the inductance and Q factor of each of the inductor 100 and 200. While inductor 200 is illustrated as formed on a second substrate 208, different from substrate 108 of inductor 100, in some embodiments, substrate 208 and substrate 108 may be merged to be a single substrate. Similar to inductor 100, inductor 200 comprises third portion 202 formed on a first surface such as a top surface of substrate 208; fourth portion 206 formed on a second surface such as a bottom surface of substrate 208; and TGVs 204 to connect third portion 202 and fourth portion 206. Substrate 208 may also be formed of glass.

Moreover, with reference to FIG. 2, inductor 100 is shown to comprise four turns while inductor 200 is shown to comprise three turns. Without loss of generality, any suitable number of turns may be chosen for either inductor, while keeping in mind that inductance of an inductor is directly proportional to the square of the number of turns of that inductor. Additionally or alternatively, one or both of inductors 100 and 200 may have a magnetic core such as core 110 of FIG. 1B provided to further improve their inductance values. Further, as previously discussed, given the three dimensional nature of inductors 100 and 200, the coefficient of coupling K between inductors 100 and 200 may be higher than that which may be achievable with planar inductors.

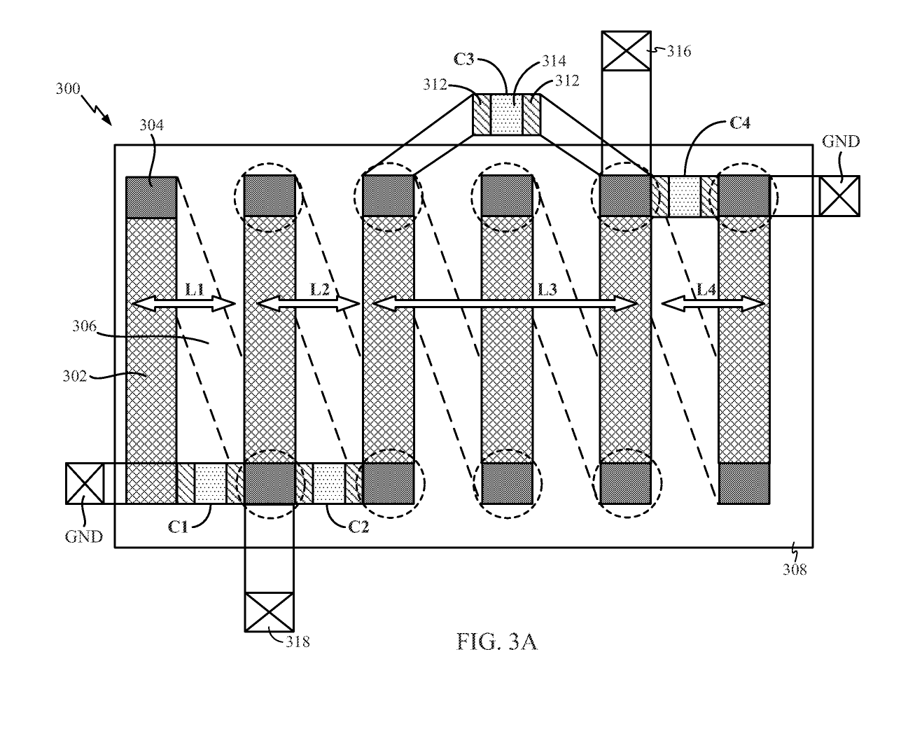

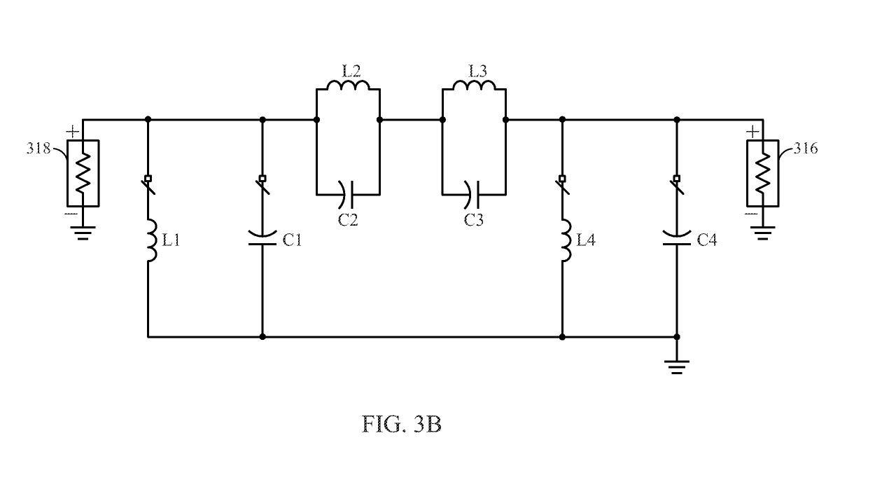

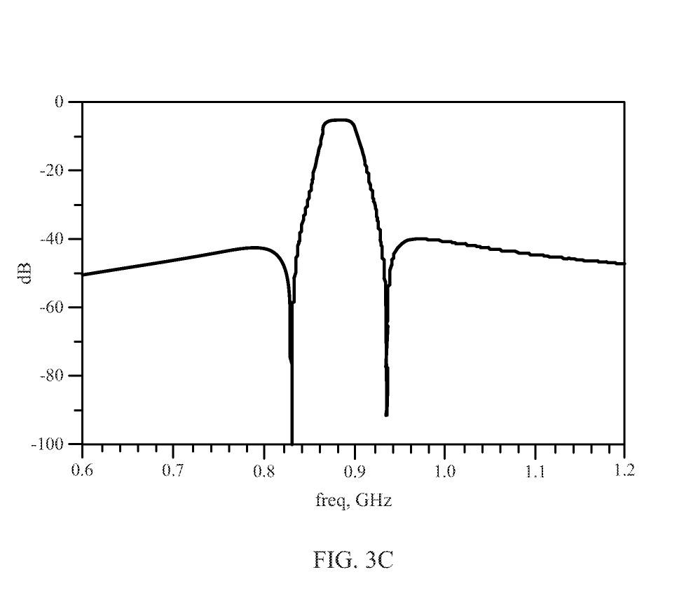

Turning now to FIG. 3A, a first 3D L-C BPF topology designated as 300, and formed according to exemplary embodiments is illustrated. FIG. 3A illustrates four inductors L1, L2, L3, and L4 formed on substrate 308. Inductor L1 is illustrated as having a single turn and formed similar to inductor 100, with first portion 302 on a first surface and second portion 306 on a second surface of substrate 308, wherein first portion 302 and second portion 306 may be connected by TGV 304. The remaining inductors L2-L4 may be formed similarly and all four inductors L1-L4 may be coupled as shown in order to align their respective magnetic fields and provide a positive mutual inductance coupling.

In addition to inductors L1-L4, FIG. 3A also illustrates four capacitors C1-C4 coupled to inductors L1-L4. Each of the four capacitors C1-C4 may be formed as a metal-insulator-metal (MIM) capacitor. For example, with reference to capacitor C3, portions 312 may be metal electrodes and the capacitive junction may be formed by insulator 314. The capacitors may be coupled to the inductors at junctions formed by the TGVs as shown. Also illustrated are two ports/terminals 316 and 318 which may be input/output pads for L-C BPF 300, and ground connections “GND.”

With reference now to FIG. 3B, a corresponding circuit-level schematic representation of L-C BPF 300 is illustrated. With combined reference to FIGS. 3A-B, the various couplings amongst inductors L1-L4 and capacitors C1-C4 is made efficient and lossless by using TGVs. The performance of the inductors in terms of Q factor and inductances enhanced by the higher coefficients of coupling is correspondingly improved, thereby improving the frequency characteristics of L-C BPF 300.

For example, with reference now to FIG. 3C, the frequency response of an L-C BPF formed according to FIGS. 3A-B is illustrated. As shown in FIG. 3B, the inductor-capacitor (L-C) pair formed by L1-C1 as well as that formed by L4-C4 is shown to he shunted to the ground, while the L-C pairs (or tanks) L2-C2 and L3-C3 are shown to be in series between the two ports/terminals 316 and 318. The L-C tanks L1-C1 and L4-C4 forming the shunts contribute to the pass band in the frequency response of FIG. 3C, while the series L-C pairs, L2-C2 and L3-C3 contribute to the zeroes. Suitable modifications to the L-C connections may provide for a smoother pass band in the frequency response of L-C BPFs in exemplary embodiments. In the following embodiments, alternative 3D L-C BPF topologies are described, while generally retaining L-C tanks such as L1-C1 and L4-C4 of L-C BPF 300 described above, while replacing L-C pairs L2-C2 and L3-C3 with various L-C filter means such as capacitors and inductors.

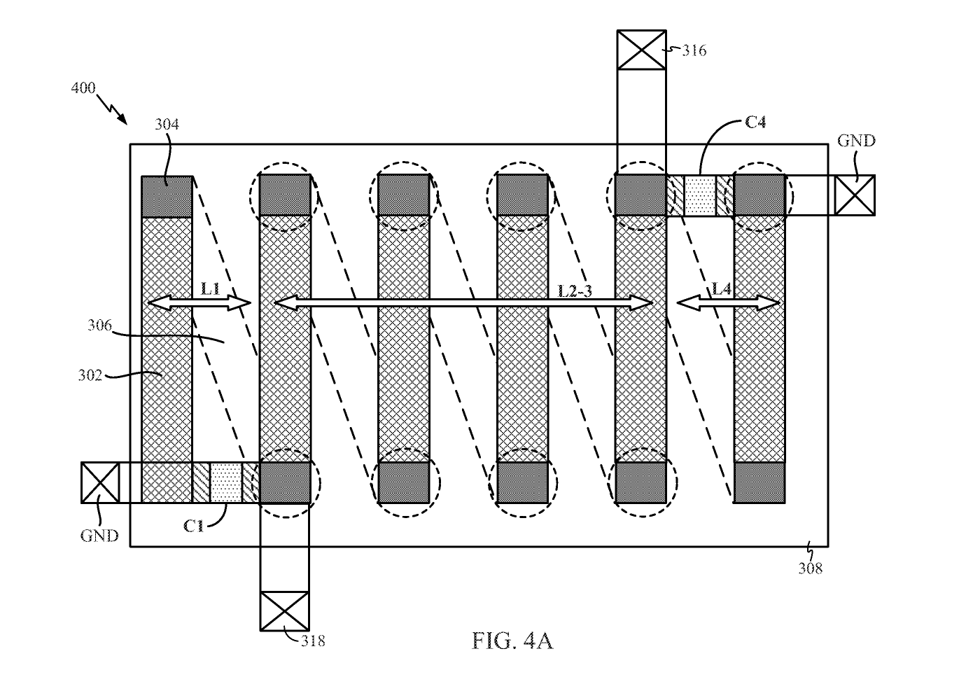

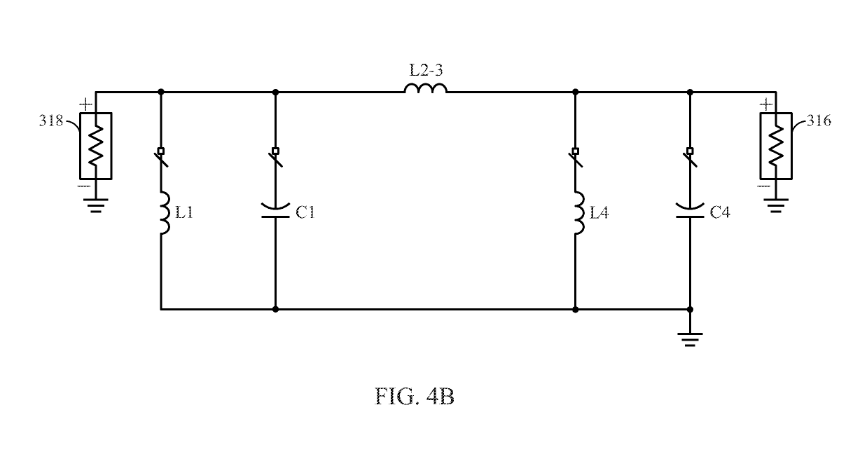

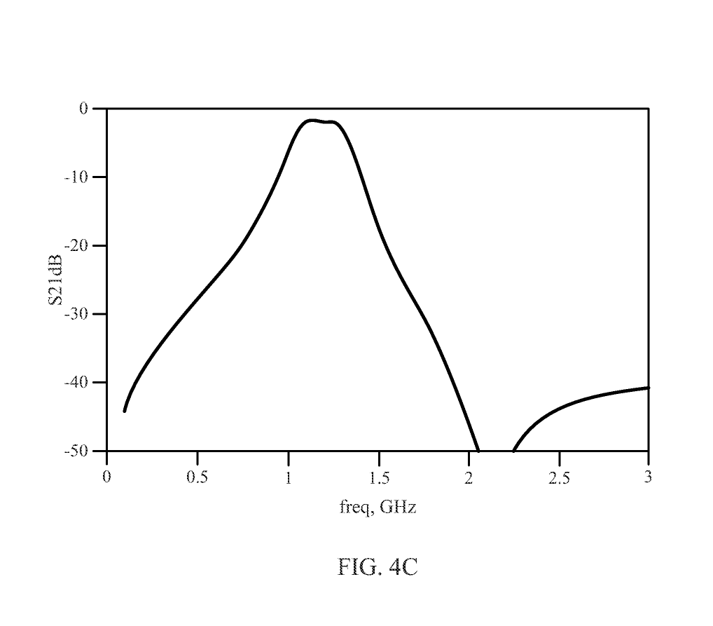

For example, with reference to FIG. 4A, a second 3D L-C BPF topology generally designated as 400 is illustrated. L-C BPF 400 is similar to L-C BPF 300 in many aspects, and for ease of understanding, the reference numerals have been substantially retained from FIG. 3A. With combined reference to FIGS. 3A and 4A, L-C BPF 400 is notably different from L-C BPF 300 in that capacitors C2 and C3 have been eliminated in L-C BPF 400. As a result, the L-C filter means, inductors L2 and L3 of L-C BPF 300 appear in series and are combined to represent a larger inductor L2-3 in L-C BPF 400.

FIG. 4B illustrates the corresponding circuit-level schematic representation of L-C BPF 400. As shown in FIG. 4B, the L-C tanks L1-C1 and L4-C4 appear as shunts, which are coupled by the combined inductor L2-3. It is observed that the circuit topology of L-C BPF 400 yields an improved frequency response characteristic in the pass band, which is free from spurious fluctuations. For example, with reference to FIG. 4C, the frequency response of L-C BPF 400 is illustrated. It can be seen from FIG. 4C that in comparison with FIG. 3C, the poles are removed and a wider and smoother pass band is observed. One reason for the improved pass band is that the combined inductor L2-3 facilitates better coupling between L-C pairs L1-C1 and L4-C4. Moreover, the inductor-coupled 3D topology of L-C BPF 400 formed using TGVs and comprising inductor L2-3 coupling L-C tanks L1-C1 and L4-C4 may provide a wide frequency range in the pass band. In one example, frequency ranges of up to 10 GHz with a minimum −39 dB rejection and free from spurious fluctuations, may be realized by high-Q coupling inductors in L-C BPF 400.

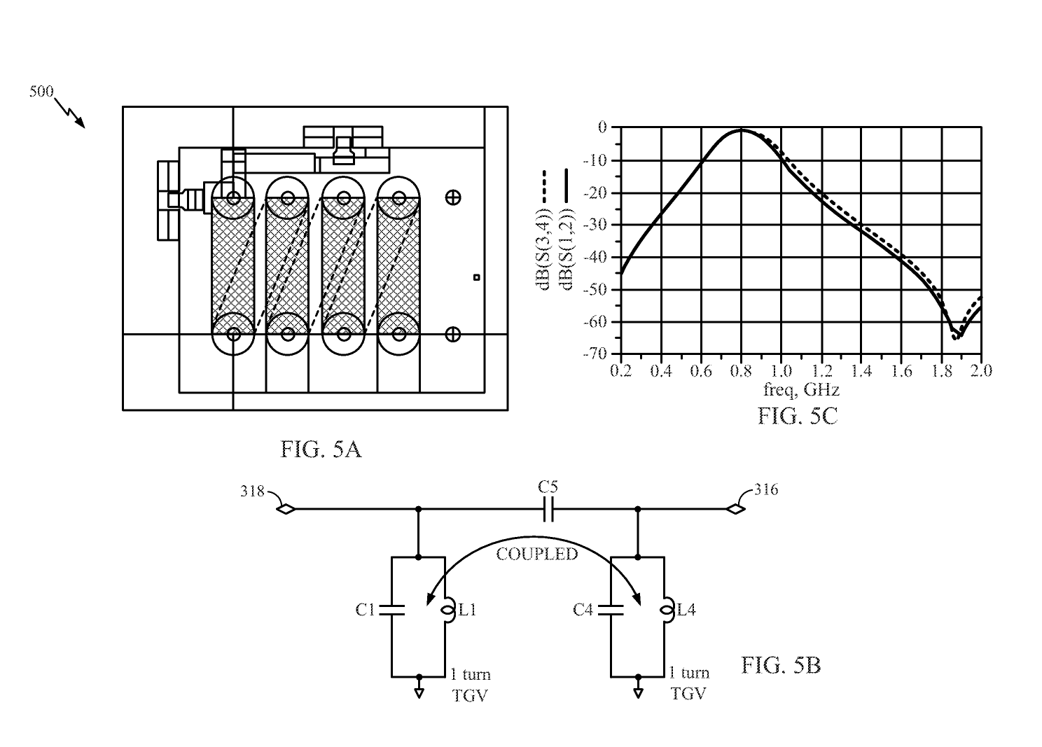

In some embodiments, improved frequency response characteristics may be realized in conventional L-C BPF topologies by configuring these conventional L-C BPFs using exemplary 3D inductors and capacitors on glass substrates using TGVs. For example, with reference to FIGS. 5A-C, yet another 3D L-C BPF topology generally designated as 500 is illustrated. FIG. 5A illustrates an L-C circuit topology which may be conventional, although configured using 3D inductors and capacitors on glass substrates using TGVs according to exemplary embodiments. The corresponding circuit-level schematic representation is presented in FIG. 5B. Compared to FIG. 4B, it can be seen that the L-C filter means, capacitor C5 in FIG. 5B replaces inductor L2-3 of FIG. 4B. With reference to the frequency response of L-C 500, which is illustrated in FIG. 5C, it is observed that the capacitor-coupled configuration of L-C BPF 500 with capacitor C5 connecting the L-C tanks L1-C1 and L4-C4 yields a smoother and wider pass band when the component inductors and capacitors are configured according to exemplary embodiments on glass substrates using TGVs than the frequency response characteristics that is achievable with conventional implementations of these L-C components.

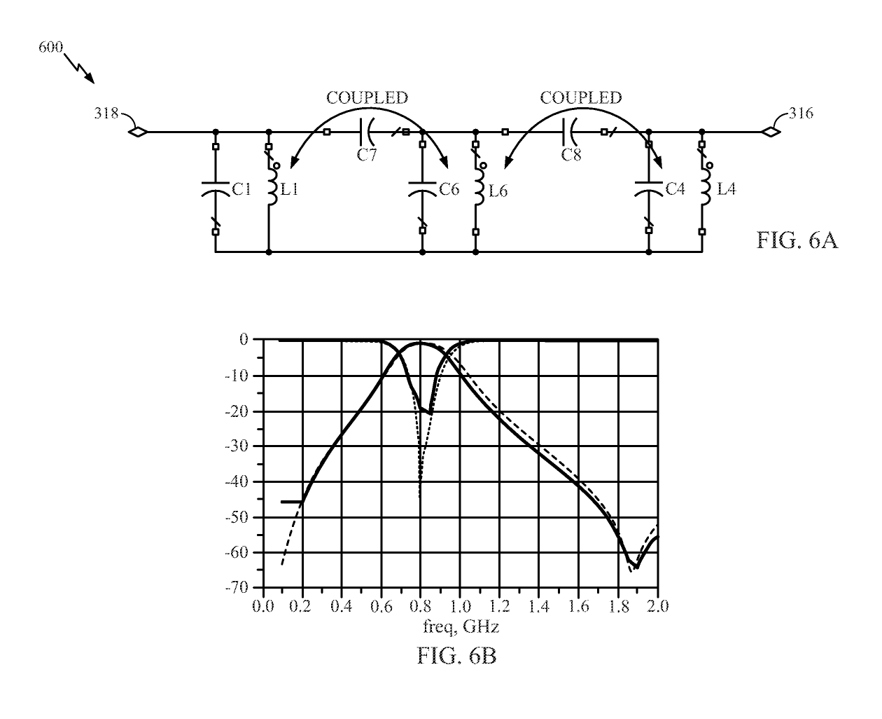

With reference to FIG. 6A, yet another L-C BPF configuration, wherein the circuit topology may be conventional, but the L-C components therein may be formed according to exemplary embodiments, is illustrated. In order to arrive at the configuration of L-C BPF 600 of FIG. 6A, the L-C filter means comprising yet another L-C tank coupled by series capacitors may be added between L-C tanks L1-C1 and L4-C4 of L-C BPF 500 of FIG. 5A. Accordingly, L-C BPF 600 further includes L-C tank C6-L6 coupled to L-C tanks L1-C1 and C4-L4 through capacitors C7 and C8. The enhanced coupling derived from the additional components, capacitors C6, C7, C8 and inductor L6 provides the frequency response illustrated in FIG. 6B, when compared to the frequency response illustrated in FIG. 5B.

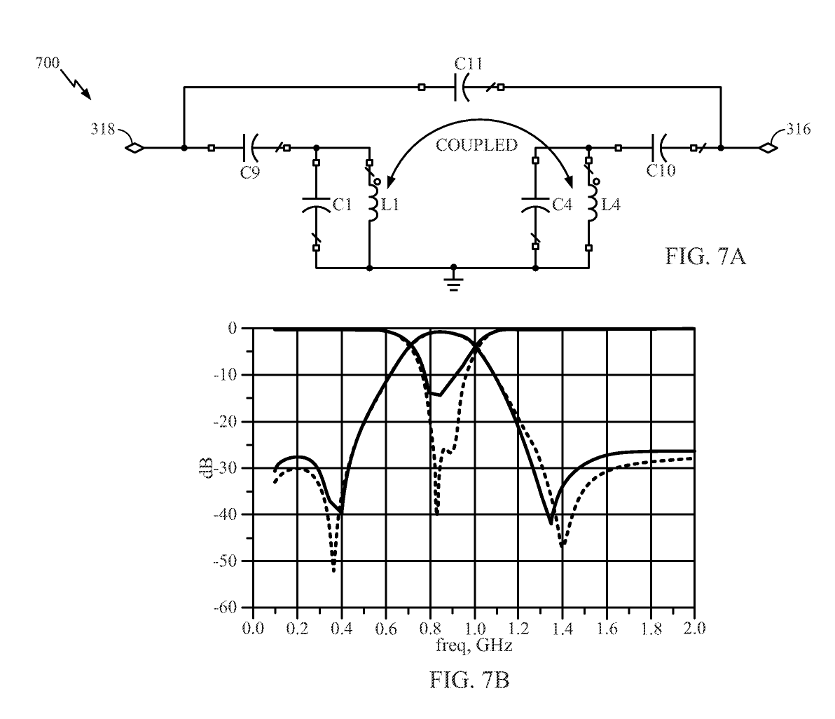

Yet another L-C BPF configuration, wherein the circuit topology may be conventional, but the L-C components therein may be formed according to exemplary embodiments, is illustrated in FIG. 7A. Once again, starting from L-C BPF 500 of FIG. 5B, L-C BPF 700 of FIG. 7A may be reached by eliminating capacitor C5 from L-C BPF 500 and adding the L-C filter means, capacitors C9, C10, and C11, as shown. The altered coupling between L-C capacitor tanks L1-C1 and L4-C4 may result in changes to the frequency response characteristics, as are depicted by FIG. 7B.

Accordingly, it can be seen that performance and frequency response characteristics of L-C BPF circuits may be improved by configuring the L-C BPFs with component L-C filter means such as inductors and capacitors on glass substrates using TGVs according to exemplary embodiments.

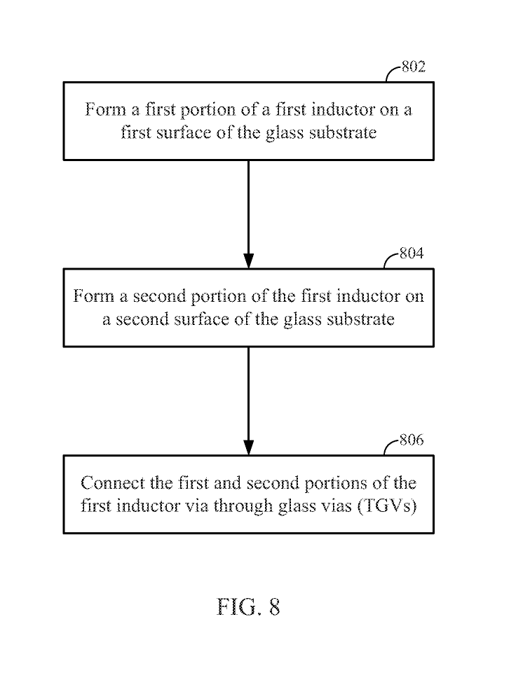

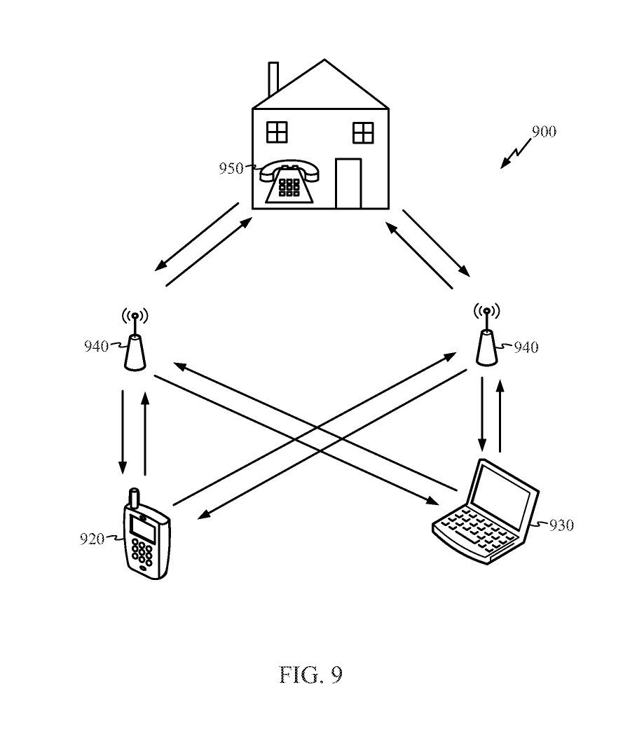

It will be appreciated that embodiments include various methods for performing the processes, functions and/or algorithms disclosed herein. For example, as illustrated in FIG. 8, an embodiment can include a method of forming an L-C filter circuit on a glass substrate (e.g. 108 of FIG. 1) comprising: forming a first portion (e.g. 102 of FIG. 1) of a first inductor (e.g. 100 of FIG. 1) on a first surface of the glass substrate—Block 802; forming a second portion (106) of the first inductor on a second surface of the glass substrate—Block 804; and connecting the first and second portions of the first inductor via through-glass-vias (TGVs) (e.g. 104 of FIG. 1)—Block 806.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, an embodiment of the invention can include a computer readable media embodying a method for L-C circuits on a glass substrate using TGVs. Accordingly, the invention is not limited to illustrated examples and any means for performing the functionality described herein are included in embodiments of the invention. Additional aspects are disclosed in the attached Appendix A, which forms part of this disclosure and is expressly incorporated herein in its entirety.

FIG. 9 illustrates an exemplary wireless communication system 900 in which an embodiment of the disclosure may be advantageously employed. For purposes of illustration, FIG. 9 shows three remote units 920, 930, and 950 and two base stations 940. In FIG. 9, remote unit 920 is shown as a mobile telephone, remote unit 930 is shown as a portable computer, and remote unit 950 is shown as a fixed location remote unit in a wireless local loop system. For example, the remote units may be mobile phones, hand-held personal communication systems (PCS) units, portable data units such as personal data assistants. GPS enabled devices, navigation devices, set top boxes, music players, video players, entertainment units, fixed location data units such as meter reading equipment, or any other device that stores or retrieves data or computer instructions, or any combination thereof. Although FIG. 9 illustrates remote units according to the teachings of the disclosure, the disclosure is not limited to these exemplary illustrated units. Embodiments of the disclosure may be suitably employed in any device which includes active integrated circuitry including memory and on-chip circuitry for test and characterization

The foregoing disclosed devices and methods are typically designed and are configured into GDSII and GERBER computer files, stored on a computer readable media. These files are in turn provided to fabrication handlers who fabricate devices based on these files. The resulting products are semiconductor wafers that are then cut into semiconductor die and packaged into a semiconductor chip. The chips are then employed in devices described above

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

What is claimed is:

1. A method of forming an L-C filter circuit on a glass substrate comprising:
forming a first portion of a first inductor on a first surface of the glass substrate;
forming a second portion of the first inductor on a second surface of the glass substrate; and
connecting the first and second portions of the first inductor via through-glass-vias (TGVs).

2. The method of claim 1, wherein the second portion is formed at an angle relative to the first portion to allow for overlapping connection points of the TGVs.

3. The method of claim 1, further comprising:
forming a third portion of a second inductor on the first surface of the glass substrate;
forming a fourth portion of the second inductor on the second surface of the glass substrate;
connecting the third and fourth portions via TGVs; and
positioning the first and second inductors to align their respective magnetic fields to provide a mutual inductance coupling.

4. The method of claim 3, further comprising:
forming a MIM (metal-insulator-metal) capacitor between the first and second inductor; and
coupling the first and second inductor through the MIM capacitor.

5. The method of claim 1, further comprising:
providing a magnetic material between the first portion and the second portion, to form a magnetic core of the first inductor.

6. An L-C filter circuit comprising:
a glass substrate;
a first portion of a first inductor formed on a first surface of the glass substrate;
a second portion of the first inductor formed on a second surface of the glass substrate; and
a first set of through-glass-vias (TGVs) configured to connect the first and second portions of the first inductor.

7. The L-C filter circuit of claim 6, wherein the second portion is formed at an angle relative to the first portion to allow for overlapping connection points of the TGVs.

8. The L-C filter circuit of claim 6, further comprising:
a third portion of a second inductor formed on the first surface of the glass substrate;
a fourth portion of the second inductor formed on the second surface of the glass substrate; and
a second set of TGVs configured to connect the third and fourth portions, wherein the first and second inductors are positioned such that their magnetic fields are aligned to provide a mutual inductance coupling.

9. The L-C filter circuit of claim 8, further comprising:
a metal-insulator-metal (MIM) capacitor formed between the first and second inductor, such that the first and second inductor are coupled through the MIM capacitor.

10. The LC filter circuit of claim 6, further comprising:
a magnetic material positioned between the first portion and the second portion, such that the magnetic material forms a magnetic core of the first inductor.

11. The L-C filter circuit of claim 6 integrated in a semiconductor die.

12. The L-C filter circuit of claim 6, integrated into a device selected from the group consisting of a set top box, music player, video player, entertainment unit, navigation device, communications device, personal digital assistant (PDA), fixed location data unit, and a computer.

13. A method of forming an L-C filter circuit on a glass substrate comprising:
step for forming a first portion of a first inductor on a first surface of the glass substrate;
step for forming a second portion of the first inductor on a second surface of the glass substrate; and
step for connecting the first and second portions of the first inductor via through-glass-vias (TGVs).

14. The method of claim 13, wherein the second portion is formed at an angle relative to the first portion to allow for overlapping connection points of the TGVs.

15. The method of claim 13, further comprising:
step for forming a third portion of a second inductor on the first surface of the glass substrate;
step for forming a fourth portion of the second inductor on the second surface of the glass substrate;
step for connecting the third and fourth portions via TGVs; and
step for positioning the first and second inductors to align their respective magnetic fields to provide a mutual inductance coupling.

16. The method of claim 15, further comprising:
step for forming a metal-insulator-metal (MIM) capacitor between the first and second inductor; and
step for coupling the first and second inductor through the MIM capacitor.

17. The method of claim 13, further comprising:
step for providing a magnetic material between the first portion and the second portion, to form a magnetic core of the first inductor.

18. An L-C filter circuit comprising:
a substrate means formed of glass;
a first portion of a first inductance means formed on a first surface of the substrate means;
a second portion of the first inductance means formed on a second surface of the substrate means; and
a first set of through-glass-vias (TGVs) configured to connect the first and second portions of the first inductance means.

19. An L-C filter circuit comprising:
a first L-C tank comprising a first inductor and a first capacitor coupled between a high voltage supply and ground;
a second L-C tank comprising a second inductor and a second capacitor coupled between the high voltage supply and ground; and
an L-C filter means coupling the first L-C tank and the second L-C tank,
wherein the first and second inductors are three-dimensional solenoid inductors formed on a first and second surface of a glass substrate using through-glass-vias (TGVs), and
wherein the first capacitor is formed as a metal-insulator-metal (MIM) capacitor between the first inductor and the second inductor on the first surface of the glass substrate, and the second capacitor is formed as a MIM capacitor between the second inductor and the L-C filter means on the first surface of the glass substrate.

20. The L-C filter circuit of claim 19, wherein the L-C filter means comprises:
a third L-C tank comprising a third inductor and a third capacitor coupled between a high voltage supply and ground;
a fourth L-C tank comprising a fourth inductor and a fourth capacitor coupled between the high voltage supply and ground, and
wherein the third capacitor is formed as a MIM capacitor between the first inductor and the third inductor on the first surface of the glass substrate, and the fourth capacitor is formed as a MIM capacitor between the fourth inductor and the second inductor on the first surface of the glass substrate.

21. The L-C filter circuit of claim 19, wherein the L-C filter means comprises a fifth inductor formed as a three-dimensional solenoid inductor formed on the first and second surface of the glass substrate using TGVs.

22. The L-C filter circuit of claim 19, wherein the L-C filter means comprises a fifth capacitor formed as a MIM capacitor between the first inductor and the second inductor on the first surface of the glass substrate.

23. The L-C filter circuit of claim 19, wherein the L-C filter means comprises:
a sixth L-C tank comprising a sixth inductor and a sixth capacitor coupled between a high voltage supply and ground;
a seventh capacitor coupling the first L-C tank and the sixth L-C tank; and
an eighth capacitor coupling the sixth L-C tank and the second L-C tank,
wherein the sixth inductor is three-dimensional solenoid inductors formed on the first and second surface of a glass substrate using TGVs, and
wherein the sixth, seventh, and eighth capacitors are formed as MIM capacitors.

24. The L-C filter circuit of claim 19, wherein the L-C filter means comprises:
a ninth capacitor coupled between high voltage supply and the first L-C tank;
a tenth capacitor coupled between the second L-C tank and high voltage supply; and
an eleventh capacitor coupled to the ninth and tenth capacitors,
wherein the ninth, tenth, and eleventh capacitors are formed as MIM capacitors.

25. The L-C filter circuit of claim 19 integrated in a semiconductor die.

26. The L-C filter circuit of claim 19, integrated into a device selected from the group consisting of a set top box, music player, video player, entertainment unit, navigation device, communications device, personal digital assistant (PDA), fixed location data unit, and a computer.
